(19) United States
(12) Patent Application Publication
(10) Pub. No.: US 2015/0048449 A1
(43) Pub. Date: Feb. 19, 2015

(54) High Voltage Semiconductor Device and Method of Forming the Same

(71) Applicant: Samsung Electronics Co., Ltd., Suwon-si (KR)

(72) Inventors: Changki Jeon, Gimpo-si (KR); Minsuk Kim, Bucheon-si (KR); Jeongho Kim, Suwon-si (KR); Yongcheol Choi, Goyang-si (KR)

(21) Appl. No.: 14/321,018

(22) Filed: Jul. 1, 2014

(30) Foreign Application Priority Data
Aug. 19, 2013 (KR) 10-2013-0098088

(51) Int. Cl. H01L 29/78

(52) U.S. Cl. CPC H01L 29/7817
USPC 257/337

(57) ABSTRACT

A high voltage semiconductor device includes a semiconductor substrate having a first conductivity type and including a low voltage part and a high voltage part, a semiconductor layer having a second conductivity type on the semiconductor substrate, a body region having the first conductivity type on the semiconductor layer, a first buried layer having the second conductivity type between the high voltage part of the semiconductor substrate and the semiconductor layer, and a second buried layer having the first conductivity type and having sidewalls inside sidewalls of the first buried layer and extending deeper into the substrate than the first buried layer. A surface of the body region adjacent the substrate is spaced apart from a surface of the second buried layer remote from the substrate such that a portion of the semiconductor layer is disposed therebetween.

### CROSS-REFERENCE TO RELATED APPLICATION

This application claims priority under 35 U.S.C. §119 to Korean Patent Application No. 10-2013-0098088, filed Aug. 19, 2013, in the Korean Intellectual Property Office, the entire contents of which are hereby incorporated herein by reference.

### FIELD

Some embodiments of the inventive concept relate generally to semiconductor devices and, more particularly, to high voltage semiconductor devices and methods of forming the same.

### BACKGROUND

A high voltage integrated circuit (HVIC), or high voltage semiconductor device, may include one or more high voltage transistors and low voltage circuits that are disposed on one chip. High voltage integrated circuits are mainly used in power control systems such as a switching power supply and/or a motor driver. A high voltage integrated circuit may include a high voltage part, a low voltage part, and a junction termination part disposed between the high voltage part and the low voltage part. The high voltage part should typically withstand high voltages of at least hundreds of volts.

### SUMMARY

Some embodiments of the inventive concept provide a high voltage semiconductor device. The high voltage semiconductor device includes a semiconductor substrate including a low voltage part and a high voltage part. The semiconductor substrate has a first conductivity type. The high voltage semiconductor device includes a semiconductor layer on the semiconductor substrate. The semiconductor layer has a second conductivity type. The high voltage semiconductor device includes a body region on the semiconductor layer. The body region has the first conductivity type. The body region has a first surface adjacent the substrate and a second surface remote from the substrate. The high voltage semiconductor device includes a first buried layer between the high voltage part of the semiconductor substrate and the semiconductor layer. The first buried layer has the second conductivity type. The high voltage semiconductor device includes a second buried layer having sidewalls inside sidewalls of the first buried layer and extending deeper into the substrate than the first buried layer. The second buried layer has the first conductivity type. The second buried layer has a first surface adjacent the substrate and a second surface remote from the substrate. The first surface of the body region is spaced apart from the second surface of the second buried layer such that a portion of the semiconductor layer is disposed therebetween. A dopant concentration of the first buried layer is higher than a dopant concentration of the semiconductor layer. A dopant concentration of the second buried layer is higher than a dopant concentration of the semiconductor substrate.

In some embodiments, the sidewalls of the first buried layer may laterally protrude from the sidewalls of the second buried layer.

In further embodiments, a distance between the sidewalls of the first buried layer and the sidewalls of the second buried layer may be at least about 5 μm.

In still further embodiments, the high voltage semiconductor device may include a level shift element between the high voltage part and the low voltage part of the semiconductor substrate. The level shift element may shift up the voltage level of a signal from the low voltage part to provide the signal at a higher voltage level to the high voltage part. The high voltage semiconductor device may include a third buried layer between the semiconductor substrate and a portion of the semiconductor layer adjacent to the level shift element. The third buried layer may have the second conductivity type. The high voltage semiconductor device may include a fourth buried layer having sidewalls inside sidewalls of the third buried layer and extending deeper into the substrate than the third buried layer. The fourth buried layer may have the first conductivity type.

In some embodiments, the sidewalls of the third buried layer may laterally protrude from the sidewalls of the fourth buried layer.

In further embodiments, a distance between the sidewalls of the third buried layer and the sidewalls of the fourth buried layer may be at least about 5 μm.

In still further embodiments, the level shift element may be a laterally diffused metal-oxide-semiconductor (LDMOS) transistor including a source region, a drain region, and a gate electrode therebetween. The third buried layer may vertically overlap the drain region.

In some embodiments, the high voltage semiconductor device may include an isolation region between the third buried layer and the first buried layer. The isolation region may have the first conductivity type.

In further embodiments, the first buried layer may be on a substantial portion of the high voltage part of the semiconductor substrate.

In still further embodiments, a high electric field may be generated at a surface of the first buried layer contacting a surface of the second buried layer during operation of the high voltage semiconductor device.

In some embodiments, the first conductivity type may be a P-type and the second conductivity type may be an N-type.

In further embodiments, the first conductivity type may be an N-type and the second conductivity type may be a P-type.

Some embodiments of the inventive concept provide a high voltage semiconductor device. The high voltage semiconductor device includes a semiconductor substrate having a first conductivity type. The high voltage semiconductor device includes a semiconductor layer having a second conductivity type on the semiconductor substrate. The high voltage semiconductor device includes a region having the first conductivity type on the semiconductor layer. The high voltage semiconductor device includes a first buried layer having the second conductivity type extending into the semiconductor substrate and separated from the region by a first portion of the semiconductor layer. The high voltage semiconductor device includes a second buried layer having sidewalls inside sidewalls of the first buried layer and extending deeper into the semiconductor substrate than the first buried layer. The second buried layer has the first conductivity type. A dopant concentration of the first buried layer is higher than a dopant concentration of the semiconductor layer. A dopant concentration of the second buried layer is higher than a dopant concentration of the semiconductor substrate.

In some embodiments, a high electric field may be generated at a surface of the first buried layer adjacent to the semiconductor substrate when a high voltage is applied to the semiconductor device.

In further embodiments, the dopant concentration of the first buried layer may be closer to the dopant concentration of the second buried layer than the dopant concentration of the first buried layer is to the dopant concentration of the semiconductor substrate.

In still further embodiments, an electrical field may be laterally distributed by the second buried layer during operation of the high voltage semiconductor device.

In some embodiments, a breakdown phenomenon may first occur at a bottom surface of the first buried layer when a high voltage is applied to the semiconductor device.

In further embodiments, the high voltage semiconductor device may include a level shift element between a high voltage part of the high voltage semiconductor device and a low voltage part of the high voltage semiconductor device. The level shift element may shift up the voltage level of a signal from the low voltage part to provide the signal at a higher voltage level to the high voltage part. The high voltage semiconductor device may include a third buried layer having the second conductivity type extending into the semiconductor substrate and separated from the level shift element by a second portion of the semiconductor layer. The high voltage semiconductor device may include a fourth buried layer having sidewalls inside sidewalls of the first buried layer and extending deeper into the semiconductor substrate than the first buried layer. The second buried layer may have the first conductivity type. The first buried layer, second buried layer, and region may be disposed in the high voltage part of the high voltage semiconductor device.

In still further embodiments, a dopant concentration of the third buried layer may be higher than the dopant concentration of the semiconductor layer. A dopant concentration of the fourth buried layer may be higher than the dopant concentration of the semiconductor substrate.

In some embodiments, the level shift element may include a laterally diffused metal-oxide-semiconductor transistor. The third buried layer may be separated from a drain region of the level shift element by the second portion of the semiconductor layer.

### BRIEF DESCRIPTION OF THE DRAWINGS

The accompanying figures are included to provide a further understanding of the present inventive concept, and are incorporated in and constitute a part of this specification. The drawings illustrate some embodiments of the present inventive concept and, together with the description, serve to explain principles of the present inventive concept.

FIG. 1 is a schematic block diagram illustrating a high voltage semiconductor device according to some embodiments of the inventive concept;

FIG. 2 is a plan view illustrating a high voltage semiconductor device according to some embodiments of the inventive concept;

FIG. 3 is a cross-sectional view taken along a line I-I′ of FIG. 2;

FIG. 4 is a graph illustrating a dopant concentration distribution depending on a distance along a line II-IF of FIG. 3 in a portion of the high voltage part HS not containing the second buried layer;

FIG. 5 is a graph illustrating a dopant concentration distribution depending on a distance along a line II-II′ of FIG. 3 in a portion of the high voltage part HS containing the second buried layer; and

FIGS. 6 to 15 are cross-sectional views illustrating processing steps in the fabrication of the high voltage semiconductor device of FIG. 3.

### DETAILED DESCRIPTION OF THE EMBODIMENTS

Embodiments are described in detail with reference to the accompanying drawings. The inventive concept, however, may be embodied in various different forms, and should not be construed as being limited only to the illustrated embodiments set forth herein. Rather, these embodiments are provided as examples so that this disclosure will be thorough and complete, and will fully convey the concept of the inventive concept to those skilled in the art. Unless otherwise noted, like reference numerals denote like elements throughout the attached drawings and written description, and thus descriptions may not be repeated.

The terminology used herein is for the purpose of describing particular embodiments only and is not intended to be limiting of the inventive concept. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present inventive concept. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

As appreciated by the present inventive entity, devices and methods of forming devices according to various embodiments described herein may be embodied in microelectronic devices, such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Embodiments of the present inventive are described with reference to a particular polarity conductivity type for various layers/regions. However, as will be appreciated by those of skill in the art, the polarity of the regions/layers may be inverted to provide an opposite polarity device without departing from the scope of the present inventive concept.

Some embodiments of the present inventive concept may include doped regions. As is known to those of skill in the art, doped regions may be formed through epitaxial growth and/or through implantation. For example, a p-type region may be formed through epitaxial growth in the presence of a p-type dopant or through implantation of p-type dopants in an undoped, p-type or n-type epitaxial layer. The structure that results from epitaxial growth differs from that that results from implantation. Thus, the terms “epitaxial region” and “implanted region” structurally distinguish differing regions and may be used herein as a recitation of structural characteristics of the regions and/or as recitations of methods of forming such regions.

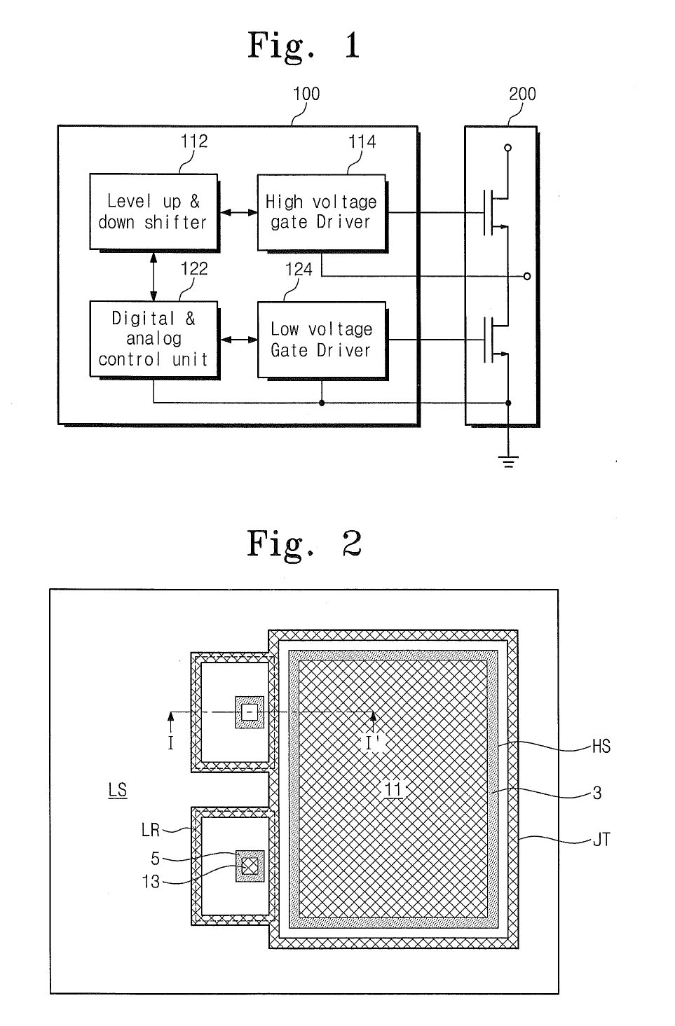

FIG. 1 is a schematic block diagram illustrating a high voltage semiconductor device according to some embodiments of the inventive concept. Referring to FIG. 1, a high voltage semiconductor device 100 includes a level up/down shifter 112, a high voltage gate driver 114, a digital/analog control unit 122, and a low voltage gate driver 124. The high voltage gate driver 114 is in a high voltage part HS of the semiconductor device 100. The low voltage gate driver 124 is in a low voltage part LS of the semiconductor device 100. The high voltage semiconductor device 100 may be electrically connected to a load 200. The load 200 may include a metal-oxide-semiconductor field effect transistor (MOSFET) or insulated gate bi-polar transistor (IGBT) for driving a motor or illuminator included in an electronic product such as a washer or a refrigerator. If the load 200 is included in household appliances, a voltage of about 600V may be applied to the load 200. If the load 200 is included in industry electronics, a voltage of about 1200V may be applied to the load 200.

The high voltage gate driver 114 may apply a high voltage (e.g., about 600V or more) electrically floated from a ground to a gate of the load 200 in response to a control signal received from the level up/down shifter 112. The level up/down shifter 112 may include a level up shifter and/or a level down shifter. For example, the level up shifter may be a laterally diffused metal-oxide-semiconductor (LDMOS) transistor. For example, the level down shifter may be a P-type metal-oxide-semiconductor (PMOS) transistor. A high voltage of about 600V or more may be applied to each of the level up shifter and the level down shifter.

The digital/analog control unit 122 may receive or transmit a control signal. The low voltage gate driver 124 may directly receive or transmit a control signal. The low voltage gate driver 124 may apply a low voltage to a gate of the load 200 in response to the control signal.

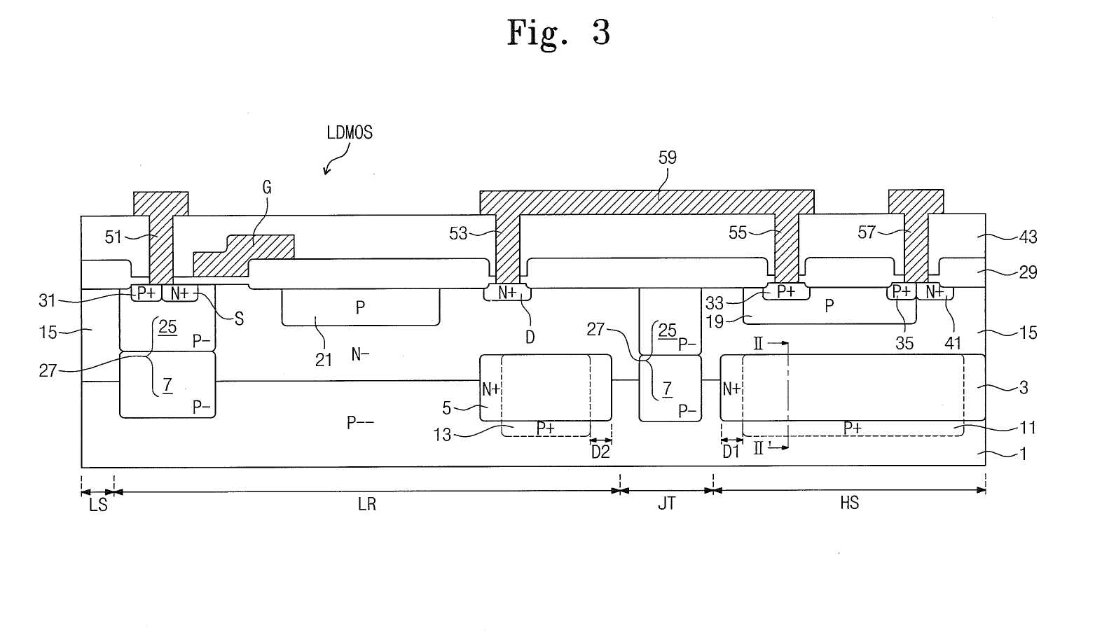

FIG. 2 is a plan view illustrating a high voltage semiconductor device according to some embodiments of the inventive concept. FIG. 3 is a cross-sectional view taken along a line I-I′ of FIG. 2. As illustrated in FIGS. 2 and 3, a high voltage semiconductor device according to some embodiments of the inventive concept includes a high voltage part HS having an island-shape and a low voltage part LS surrounding the high voltage part HS. The high voltage gate driver 114 described with reference to FIG. 1 is disposed in the high voltage part HS. The low voltage gate driver 124 of FIG. 1 is disposed in the low voltage part LS. The high voltage part HS is surrounded by a junction termination region JT. Thus, the high voltage part HS is electrically isolated from the low voltage part LS by the junction termination region JT. For example, the junction termination region JT includes a P-type isolation region 27. A level shift element region LR for a level shift element is disposed between the high voltage part HS and the low voltage part LS. For example, the level shift element is a laterally diffused metal-oxide-semiconductor (LDMOS) transistor.

As illustrated in FIG. 3, a semiconductor substrate 1 is doped with P-type dopants. An N-type semiconductor epitaxial layer 15 is disposed on the semiconductor substrate 1. A first insulating layer 29 is disposed on the semiconductor epitaxial layer 15. A thickness of the first insulating layer 29 is varied depending on its position. A thick portion of the first insulating layer 29 functions as a device isolation layer. A thin portion of the first insulating layer 29 functions as a gate insulating layer or a pad oxide layer. The first insulating layer 29 under a gate electrode G functions as the gate insulating layer. A second insulating layer 43 is disposed on the first insulating layer 29. The second insulating layer 43 is an interlayer insulating layer.

A first buried layer 3 is disposed between the semiconductor substrate 1 and the semiconductor epitaxial layer 15 in the high voltage part HS. The first buried layer 3 is doped with N-type dopants. A concentration of the N-type dopants doped in the first buried layer 3 is greater than a concentration of the N-type dopants doped in the semiconductor epitaxial layer 15. The first buried layer 3 is distributed throughout the high voltage part HS. In other words, the first buried layer 3 is on a substantial portion of the high voltage part HS. A second buried layer 11 extends from the inside of the first buried layer 3 into the semiconductor substrate 1. The second buried layer 11 is doped with P-type dopants. A concentration of the P-type dopants doped in the second buried layer 11 is greater than a concentration of the P-type dopants doped in the semiconductor substrate 1. A sidewall of the first buried layer 3 laterally protrudes from a sidewall of the second buried layer 11. In other words, the second buried layer 11 has sidewalls inside sidewalls of the first buried layer 3 and extends deeper into the substrate than the first buried layer 3. A distance D1 between the sidewalls of the first buried layer 3 and the sidewalls of the second buried layer 11 may be at least about 5 μm.

A first high voltage interconnection electrode 57 is disposed to penetrate the second insulating layer 43 and the first insulating layer 29 in the high voltage part HS. A first contact region 35 and a second contact region 41 are disposed in an upper portion of the semiconductor epitaxial layer 15. The first and second contact regions 35 and 41 are in contact with the first high voltage interconnection electrode 57. The first contact region 35 is a P+ dopant region. The second contact region 41 is an N+ dopant region. The second contact region 41 is in direct contact with the semiconductor epitaxial layer 15.

The gate electrode G is disposed on the first insulating layer 29 in the level shift element region LR. A source region S is disposed in the semiconductor epitaxial layer 15 at a side of the gate electrode G, and a drain region D is disposed in the semiconductor epitaxial layer 15 at another side of the gate electrode G. The source region S and the drain region D are N+ dopant regions. The drain region D is in contact with the semiconductor epitaxial layer 15. The source region S is in contact with a third contact region 31. The third contact region 31 is a P+ dopant region. A well 25 and a third buried layer 7 are disposed under the third contact region 31 and the source region S. The third buried layer 7 and the well 25 are doped with P-type dopants. A concentration of the P-type dopants doped in the third buried layer 7 is substantially equal to a concentration of the P-type dopants doped in the well 25.

The well 25 and the third buried layer 7 constitute the isolation region 27. The third buried layer 7 extends into the semiconductor substrate 1. A source electrode 51 penetrates the second insulating layer 43 and the first insulating layer 29. The source electrode 51 is in contact with the source region S and the third contact region 31. Since the source electrode 51 is in contact with both the source region S and the third contact region 31, a bias of the well 25 may be applied through the source electrode 51. A first body region 21 is disposed between the source region S and the drain region D. The first body region 21 is spaced apart from the source and drain regions S and D. The first body region 21 is doped with P-type dopants. A bottom surface of the first body region 21 is spaced apart from the semiconductor substrate 1. The first body region 21 functions as a resistor between the source region S and the drain region D.

The drain region D is in contact with a drain electrode 53 penetrating the second insulating layer 43 and the first insulating layer 29. The drain electrode 53 is connected to a high voltage interconnection 59 disposed on the second insulating layer 43. A portion of the high voltage interconnection 59 extends into the high voltage part HS to be in contact with a second high voltage interconnection electrode 55 that penetrates the second and first insulating layers 43 and 29 in the high voltage part HS. A fourth contact region 33 is disposed in the semiconductor epitaxial layer 15 under the second high voltage interconnection electrode 55. The fourth contact region 33 is a P+ dopant region. The first contact region 35 and the fourth contact region 33 are electrically connected to each other through a second body region 19. The second body region 19 is doped with P-type dopants. The second body region 19 has a lower P-type dopant concentration than the fourth contact region 33. The second body region 19 is spaced apart from the first buried layer 3. The second body region 19 functions as a resistor between the second high voltage interconnection electrode 55 and the first high voltage interconnection electrode 57.

A fourth buried layer 5 is disposed at an interface between the semiconductor substrate 1 and the semiconductor epitaxial layer 15 under the drain region D in the level shift element region LR. The fourth buried layer 5 is doped with N-type dopants. A concentration of the N-type dopants doped in the fourth buried layer 5 is greater than a concentration of the N-typed dopants doped in the semiconductor epitaxial layer 15. A fifth buried layer 13 extends from the inside of the fourth buried layer 5 into the semiconductor substrate 1. The fifth buried layer 13 is doped with P-type dopants. A concentration of the P-type dopants doped in the fifth buried layer 13 is greater than the concentration of the P-type dopants doped in the semiconductor substrate 1. A sidewall of the fourth buried layer 5 laterally protrudes from a sidewall of the fifth buried layer 13. In other words, the fifth buried layer 13 has sidewalls inside sidewalls of the fourth buried layer 5 and extends deeper into the substrate than the fourth buried layer 5. A second distance D2 between the sidewalls of the fourth buried layer 5 and the sidewalls of the fifth buried layer 13 may be at least about 5 μm.

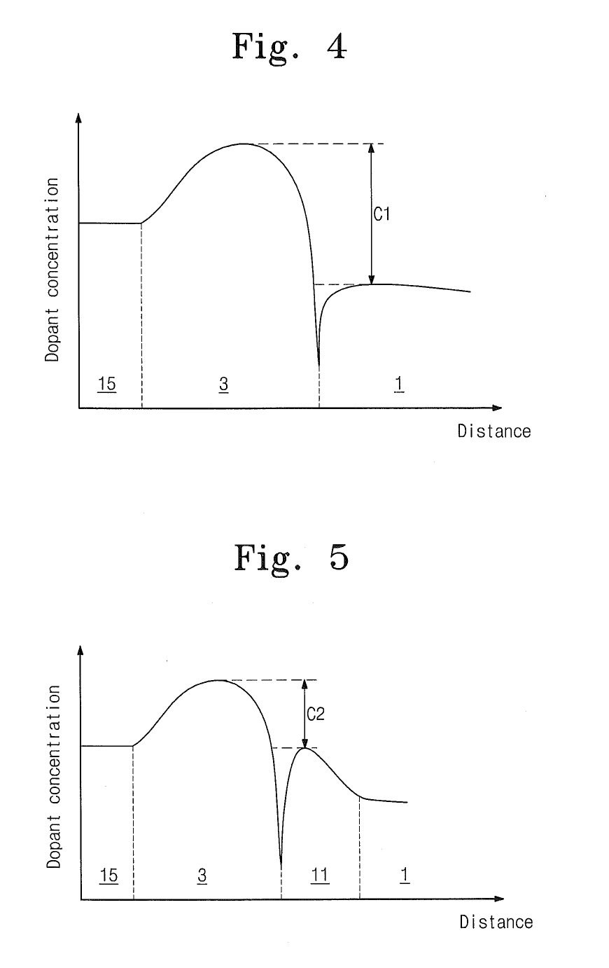

FIG. 4 is a graph illustrating a dopant concentration distribution depending on a distance along a line II-II′ of FIG. 3 in a portion of the high voltage part HS not containing the second buried layer. FIG. 5 is a graph illustrating a dopant concentration distribution depending on a distance along a line II-II′ of FIG. 3 in a portion of the high voltage part HS containing the second buried layer.

As illustrated in FIG. 4, there is a large concentration difference C1 between the N-type first buried layer 3 and the P-type semiconductor substrate 1 in the portion of the high voltage part HS not containing the second buried layer 11. However, as illustrated in FIG. 5, a concentration difference C2 between the N-type first buried layer 3 and the P-type second buried layer 11 in the portion of the high voltage part HS containing the second buried later 11 is smaller than the concentration difference C1 due to the dopant concentration of the second buried layer 11. Thus, an electric field may be laterally distributed by the second buried layer 11. Additionally, since the concentrations of the first and second buried layers 3 and 11 constituting a PN junction are high, a breakdown voltage of the first and second buried layer 3 and 11 is small. Thus, a breakdown phenomenon may first occur at the bottom surface of the first buried layer 3 when a high voltage is applied to the high voltage interconnection electrodes 55 and 57. When a breakdown phenomenon occurs, heat is generated at the portion in which the breakdown phenomenon occurs. If the heat is generated at a surface of the semiconductor epitaxial layer 15 on which elements are disposed, the elements may melt or burn and possibly cause damage and/or destroy the elements. However, according to embodiments of the inventive concept, the breakdown phenomenon first occurs at a lower portion of the semiconductor substrate 1, which may reduce the likelihood or possibly prevent the damage and/or destruction of the elements. Additionally, the first buried layer 3 is distributed throughout the high voltage part HS and the second buried 11 is also mostly distributed throughout the high voltage part HS. Thus, the breakdown phenomenon may be laterally distributed across a wider area. As a result, reliability of the high voltage semiconductor device is improved.

Additionally, since the fourth and fifth buried layers 5 and 13 are disposed under the drain electrode 53 applied with a high voltage, a breakdown phenomenon first occurs at the bottom surface of the fourth buried layer 5. Thus, the likelihood of damage of the LDMOS transistor is reduced or possibly prevented when the high voltage is applied.

Furthermore, the first and fourth buried layers 3 and 5 that are N+ regions having high concentrations may reduce or prevent a leakage current from flowing to the surface of the semiconductor epitaxial layer 15 when the high voltage semiconductor device is operated.

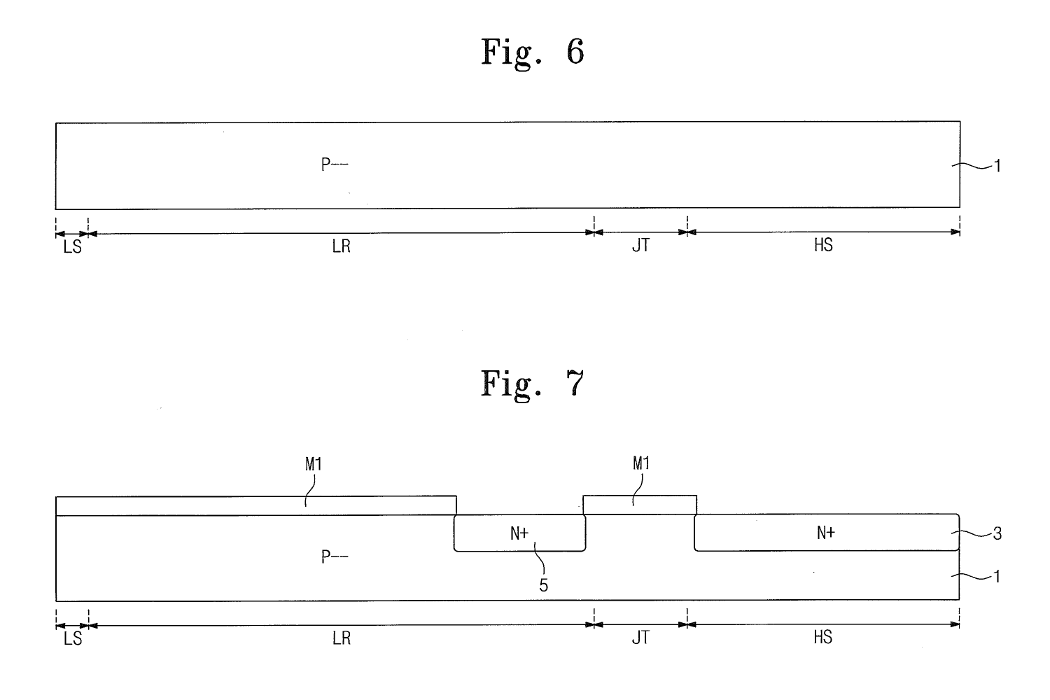

Processing steps in the fabrication of the high voltage semiconductor device of FIG. 3 will be discussed with respect to the cross-sectional views of FIGS. 6 to 15.

As illustrated in FIG. 6, a semiconductor substrate 1 is prepared including a low voltage part LS, a high voltage part HS, a junction termination region JT and a level shift element region LS. The semiconductor substrate 1 is doped with, for example, P-type dopants.

As illustrated in FIG. 7, a first mask pattern M1 is formed on a top surface of the semiconductor substrate 1. A buffer oxide layer is formed on the semiconductor substrate 1 before the formation of the first mask pattern M1. N-type dopants are injected using the first mask pattern M1 as an ion implantation mask, thereby forming the first buried layer 3 and the fourth buried layer 5 in the semiconductor substrate 1.

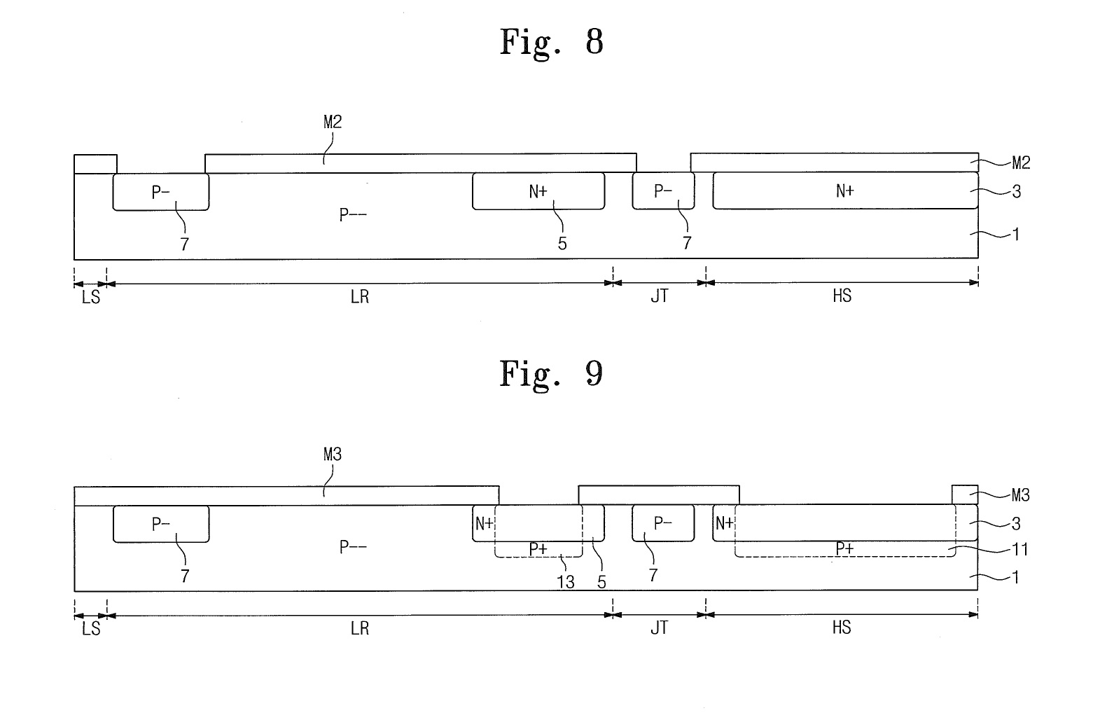

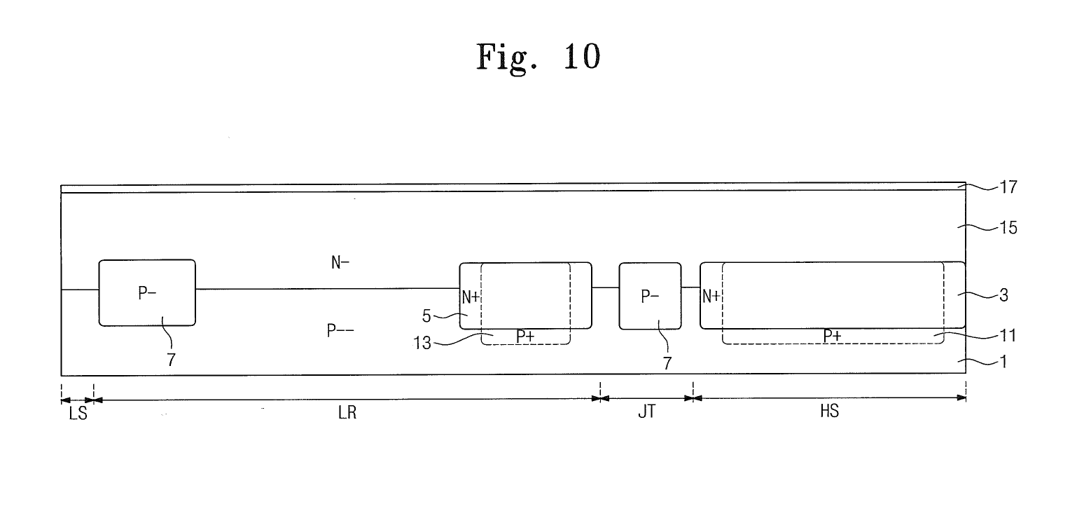

As illustrated in FIG. 8, the first mask pattern M1 is removed. Next, a second mask pattern M2 is formed on the semiconductor substrate 1. P-type dopants are injected using the second mask pattern M2 as an ion implantation mask, thereby forming the third buried layer 7 spaced apart from the first and fourth buried layers 3 and 5 in the semiconductor substrate 1. The concentration of the P-type dopants doped in the third buried layer 7 is higher than the concentration of the P-type dopants doped in the semiconductor substrate 1.

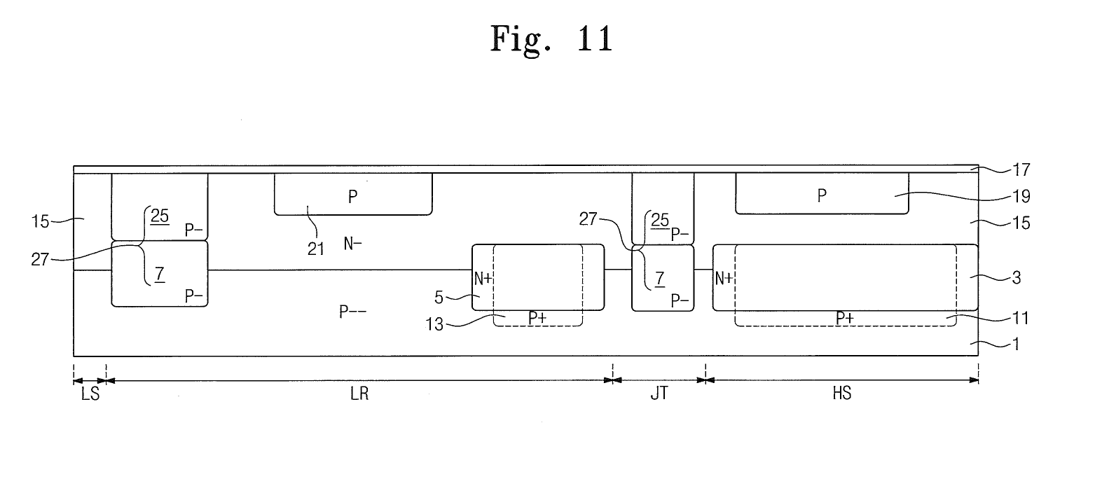

As illustrated in FIG. 9, the second mask pattern M2 is removed. A third mask pattern M3 is formed on the semiconductor substrate 1. The third mask pattern M3 includes openings respectively overlapping portions of the first and fourth buried layers 3 and 5. P-type dopants are injected using the third mask pattern M3 as an ion implantation mask, thereby forming the second and fifth buried layers 11 and 13 respectively overlapping portions of the first and fourth buried layers 3 and 5 in the semiconductor substrate 1. A dopant concentration of the second and fifth buried layers 11 and 13 is equal to or greater than that of the third buried layer 7. The second and fifth buried layers 11 and 13 extend from the first and fourth buried layers 3 and 5 into the semiconductor substrate 1, respectively. In other words, bottom surfaces of the second and fifth buried layers 11 and 13 are formed to be lower than bottom surfaces of the first and fourth buried layers 3 and 5. Widths of the second and fifth buried layers 11 and 13 are less than widths of the first and fourth buried layers 3 and 5, respectively.

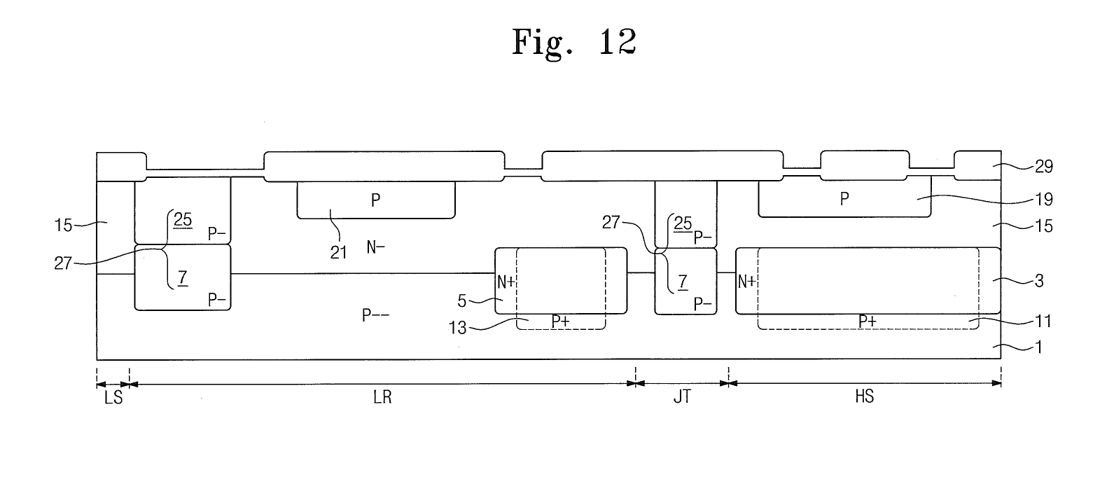

As illustrated in FIG. 10, the third mask pattern M3 is removed. Thereafter, a semiconductor epitaxial layer 15 is formed on the semiconductor substrate 1. The semiconductor epitaxial layer 15 is doped with, for example, N-type dopants. A dopant concentration of the semiconductor epitaxial layer 15 is lower than those of the first and fourth buried layers 3 and 5. The semiconductor epitaxial layer 15 may be formed using a selective epitaxial growth (SEG) method or a solid phase epitaxy (SPE) method. The semiconductor epitaxial layer 15 may be doped with the N-type dopants by an in-situ doping method or an additional ion implantation process. A thermal oxide layer 17 is formed on the semiconductor epitaxial layer 15. The dopants of the first to fifth buried layers 3, 11, 7, 5 and 13 are diffused into the semiconductor epitaxial layer 15 to a predetermined distance due to heat during the formation of the thermal oxide layer 17. Thus, the first to fifth buried layers 3, 11, 7, 5 and 13 are enlarged into the semiconductor epitaxial layer 15.

As illustrated in FIG. 11, an ion implantation process using P-type dopants is performed to form a well 25 contacting the third buried layer 7 in the semiconductor epitaxial layer 15. Additionally, an additional ion implantation process is performed to form body regions 19 and 21 respectively spaced apart from the first and fourth buried layers 3 and 5.

As illustrated in FIG. 12, nitride patterns used as oxidation preventing masks are formed on the thermal oxide layer 17 and then a local oxidation of silicon (LOCOS) process is performed to form a first insulating layer 29 having a thickness varied depending on its position. The first insulating layer 29 functions as a device isolation layer, a gate insulating layer and a pad oxide layer according to its position. Thereafter, the nitride patterns are removed.

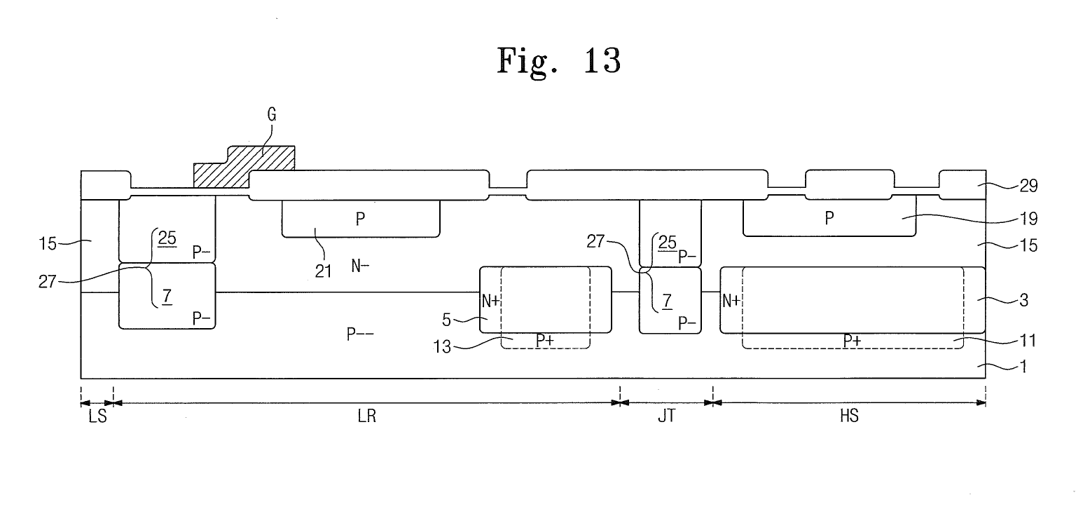

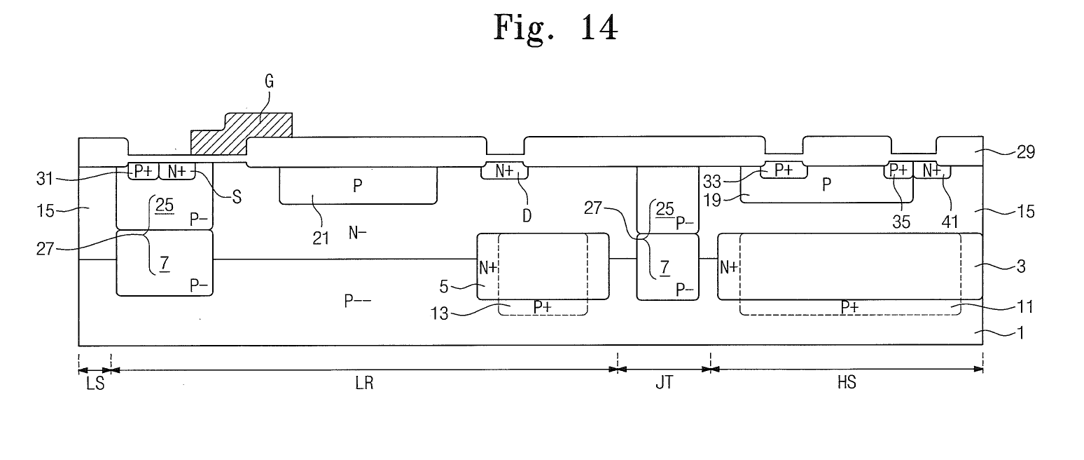

As illustrated in FIG. 13, a gate electrode G is formed on a portion of the first insulating layer 29 in the level shift element region LR.

As illustrated in FIG. 14, an ion implantation process using N-type dopants is performed to form the source region S, the drain region D, and the second contact region 41. The source region S is formed in the semiconductor epitaxial layer 15 at a side of the gate electrode G, and the drain region D is formed in the semiconductor epitaxial layer 15 at another side of the gate electrode G. The second contact region 41 is formed in the semiconductor epitaxial layer 15 at a side of the second body region 19. Next, an ion implantation process using P-type dopants is performed to form the first, third and fourth contact regions 35, 31 and 33 in the semiconductor epitaxial layer 15.

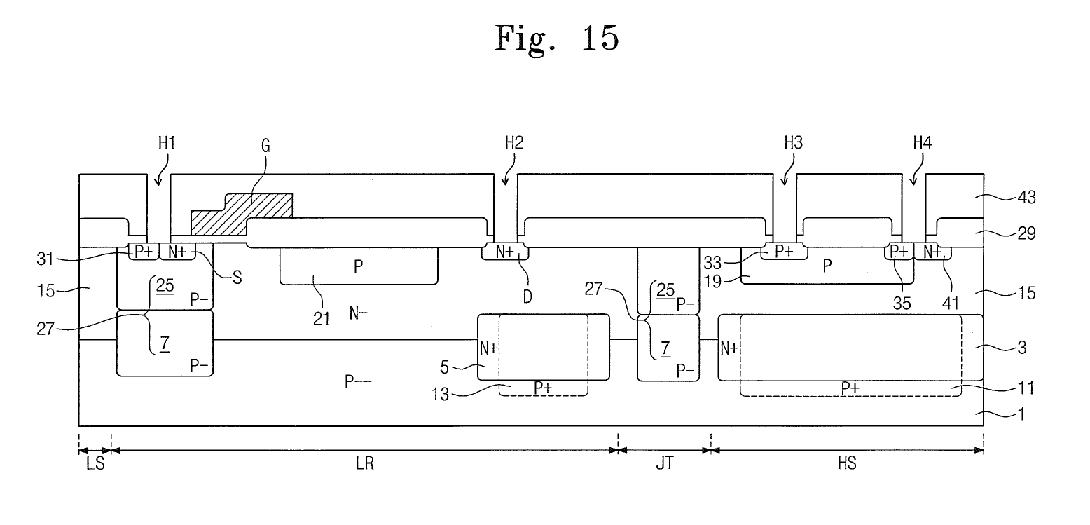

As illustrated in FIG. 15, a second insulating layer 43 is formed to cover the gate electrode G and the first insulating layer 29. The second insulating layer 43 and the first insulating layer 29 are patterned to form a plurality of contact holes H1 to H4.

Referring again to FIG. 3, a conductive layer is formed to fill the contact holes H1 to H4. The conductive layer is patterned to form the source electrode 51, the drain electrode 53, the high voltage interconnection electrodes 55 and 57 and the high voltage interconnection 59.

According to the high voltage semiconductor device of some embodiments of the inventive concept, the N-type first buried layer 3 is disposed between the P-type semiconductor substrate 1 and the N-type semiconductor epitaxial layer 15 in the high voltage part HS. A dopant concentration of the N-type first buried layer 3 is higher than that of the N-type semiconductor epitaxial layer 15. The P-type second buried layer 11 extends from the inside of the first buried layer 3 into the semiconductor substrate 1. A dopant concentration of the P-type second buried layer 11 is higher than that of the P-type semiconductor substrate 1. Thus, a high electric field may be generated at the bottom surface of the first buried layer 3 such that the breakdown phenomenon occurs at a bottom surface of the first buried layer 3. As a result, elements (e.g., a transistor and/or a capacitor) on a top surface of the semiconductor epitaxial layer 15 are less likely or possibly prevented from being damaged or broken. Additionally, the first and second buried layers 3 and 11 are disposed throughout the high voltage part such that the high electric field extends across a wider region to improve the reliability and electrostatic discharge (ESD) characteristics of the high voltage semiconductor device 100. Thus, the high voltage semiconductor device 100 may be capable of enduring a high voltage of at least about 1200V.

While the inventive concept has been described with reference to some embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A high voltage semiconductor device comprising:
a semiconductor substrate including a low voltage part and a high voltage part and having a first conductivity type;
a semiconductor layer on the semiconductor substrate and having a second conductivity type;
a body region on the semiconductor layer and having the first conductivity type, the body region having a first surface adjacent the substrate and a second surface remote from the substrate;
a first buried layer between the high voltage part of the semiconductor substrate and the semiconductor layer, the first buried layer having the second conductivity type; and
a second buried layer having sidewalls inside sidewalls of the first buried layer and extending deeper into the substrate than the first buried layer, the second buried layer having the first conductivity type and having a first surface adjacent the substrate and a second surface remote from the substrate,
wherein the first surface of the body region is spaced apart from the second surface of the second buried layer such that a portion of the semiconductor layer is disposed therebetween;
wherein a dopant concentration of the first buried layer is higher than a dopant concentration of the semiconductor layer; and
wherein a dopant concentration of the second buried layer is higher than a dopant concentration of the semiconductor substrate.

2. The high voltage semiconductor device of claim 1, wherein the sidewalls of the first buried layer laterally protrude from the sidewalls of the second buried layer.

3. The high voltage semiconductor device of claim 2, wherein a distance between the sidewalls of the first buried layer and the sidewalls of the second buried layer is at least about 5 μm.

4. The high voltage semiconductor device of claim 1, further comprising:
a level shift element between the high voltage part and the low voltage part of the semiconductor substrate, the level shift element shifting up the voltage level of a signal from the low voltage part to provide the signal at a higher voltage level to the high voltage part;
a third buried layer between the semiconductor substrate and a portion of the semiconductor layer adjacent to the level shift element, the third buried layer having the second conductivity type; and
a fourth buried layer having sidewalls inside sidewalls of the third buried layer and extending deeper into the substrate than the third buried layer, the fourth buried layer having the first conductivity type.

5. The high voltage semiconductor device of claim 4, wherein the sidewalls of the third buried layer laterally protrude from the sidewalls of the fourth buried layer.

6. The high voltage semiconductor device of claim 5, wherein a distance between the sidewalls of the third buried layer and the sidewalls of the fourth buried layer are at least about 5 μm.

7. The high voltage semiconductor device of claim 4:
wherein the level shift element is a laterally diffused metal-oxide-semiconductor (LDMOS) transistor including a source region, a drain region, and a gate electrode therebetween; and
wherein the third buried layer vertically overlaps the drain region.

8. The high voltage semiconductor device of claim 4, further comprising an isolation region between the third buried layer and the first buried layer, the isolation region having the first conductivity type.

9. The high voltage semiconductor device of claim 1, wherein the first buried layer is on a substantial portion of the high voltage part of the semiconductor substrate.

10. The high voltage semiconductor device of claim 1, wherein a high electric field is generated at a surface of the first buried layer contacting a surface of the second buried layer during operation of the high voltage semiconductor device.

11. The high voltage semiconductor device of claim 1, wherein the first conductivity type is a P-type and the second conductivity type is an N-type.

12. The high voltage semiconductor device of claim 1, wherein the first conductivity type is an N-type and the second conductivity type is a P-type.

13. A high voltage semiconductor device comprising:
a semiconductor substrate having a first conductivity type;
a semiconductor layer having a second conductivity type on the semiconductor substrate;
a region having the first conductivity type on the semiconductor layer;
a first buried layer having the second conductivity type extending into the semiconductor substrate and separated from the region by a first portion of the semiconductor layer; and
a second buried layer having sidewalls inside sidewalls of the first buried layer and extending deeper into the semiconductor substrate than the first buried layer, the second buried layer having the first conductivity type,
wherein a dopant concentration of the first buried layer is higher than a dopant concentration of the semiconductor layer; and
wherein a dopant concentration of the second buried layer is higher than a dopant concentration of the semiconductor substrate.

14. The high voltage semiconductor device of claim 13, wherein a high electric field is generated at a surface of the first buried layer adjacent to the semiconductor substrate when a high voltage is applied to the semiconductor device.

15. The high voltage semiconductor device of claim 13, wherein the dopant concentration of the first buried layer is closer to the dopant concentration of the second buried layer than the dopant concentration of the first buried layer is to the dopant concentration of the semiconductor substrate.

16. The high voltage semiconductor device of claim 15, wherein an electrical field is laterally distributed by the second buried layer during operation of the high voltage semiconductor device.

17. The high voltage semiconductor device of claim 13, wherein a breakdown phenomenon first occurs at a bottom surface of the first buried layer when a high voltage is applied to the semiconductor device.

18. The high voltage semiconductor device of claim 13, further comprising:
a level shift element between a high voltage part of the high voltage semiconductor device and a low voltage part of the high voltage semiconductor device, the level shift element shifting up the voltage level of a signal from the low voltage part to provide the signal at a higher voltage level to the high voltage part;
a third buried layer having the second conductivity type extending into the semiconductor substrate and separated from the level shift element by a second portion of the semiconductor layer; and
a fourth buried layer having sidewalls inside sidewalls of the first buried layer and extending deeper into the semiconductor substrate than the first buried layer, the second buried layer having the first conductivity type,
wherein the first buried layer, second buried layer, and region are disposed in the high voltage part of the high voltage semiconductor device.

19. The high voltage semiconductor device of claim 18, wherein a dopant concentration of the third buried layer is higher than the dopant concentration of the semiconductor layer; and
wherein a dopant concentration of the fourth buried layer is higher than the dopant concentration of the semiconductor substrate.

20. The high voltage semiconductor device of claim 18:
wherein the level shift element comprises a laterally diffused metal-oxide-semiconductor transistor; and
wherein the third buried layer is separated from a drain region of the level shift element by the second portion of the semiconductor layer.
